(19) United States
(12) Patent Application Publication
(10) Pub. No.: US 2026/0204513 A1
(43) Pub. Date: Jul. 16, 2026

(54) ION IMPLANTER AND METHOD OF ION BEAM CONTROL USING ION BEAM IMAGING SYSTEM

(71) Applicant: Applied Materials, Inc., Santa Clara, CA (US)

(72) Inventors: Alexander S. Perel, Danvers, MA (US); Allan R. Watson, Gloucester, MA (US); Zachary Page, Pembroke, NH (US)

(73) Assignee: Applied Materials, Inc., Santa Clara, CA (US)

(21) Appl. No.: 19/020,451

(22) Filed: Jan. 14, 2025

(51) Int. Cl. H01J 37/317; H01J 37/08

(52) U.S. Cl. CPC H01J 37/3171; H01J 37/08; H01J 2237/31701

(57) ABSTRACT

An ion implanter. The ion implanter may include an ion source, to generate an ion beam. The ion source may include an ion source chamber, and an adjustable electrode set, external to the ion source chamber. The ion implanter may include a set of beamline components, disposed along a beamline of the ion implanter, and arranged to direct the ion beam to a substrate position. The ion implanter may further include an in-situ beam imaging system, having at least one detector that images the ion beam in at least one location, between the ion source and the substrate position.

### FIELD OF THE DISCLOSURE

The disclosure relates generally to ion implanters, and more particularly to ion source control in ion implanters.

### BACKGROUND OF THE DISCLOSURE

Ion implantation is a process of introducing dopants or impurities into a substrate via bombardment. Ion implantation systems may comprise an ion source and a series of beam-line components. Among other things, the different beamline components may be used to accelerate, steer, filter, and focus the ion beam as the ion beam is transported from ion source to a substrate in an end station of the ion implanter.

In order to generate an ion beam having suitable properties, including suitable shape, size, position and angle, various beamline components may be adjusted or tuned. For example, a given application may require a targeted ion energy and ion current to be generated by the ion source. For a given set of ion energy/ion current, various components of the ion source may be adjusted or tuned, including electrodes that extract the ion beam. This tuning procedure may entail mechanical the setting of electrode position according to a set of known values or by tuning to a maximum current in a detector such as a Faraday cup, according to a given implantation recipe, for example. However, this tuning procedure may lead to non-optimal transmission of the ion beam

With respect to these and other considerations the present disclosure is provided.

### BRIEF SUMMARY

In one embodiment an ion implanter is provided. The ion implanter may include an ion source, to generate an ion beam. The ion source may include an ion source chamber, and an adjustable electrode set, external to the ion source chamber. The ion implanter may include a set of beamline components, disposed along a beamline of the ion implanter, and arranged to direct the ion beam to a substrate position. The ion implanter may further include an in-situ beam imaging system, having at least one detector that images the ion beam in at least one location, between the ion source and the substrate position.

In another embodiment, a method is provided. The method may include measuring a beam characteristic of the ion beam at a position along the beamline between an ion source and a substrate position. The measuring may be performed using a metrology system that includes an imaging detector. The method may further include adjusting an electrode set of the ion source, according to the beam characteristic.

### BRIEF DESCRIPTION OF THE DRAWINGS

FIG. 1 shows a side view of an exemplary ion implanter, according to embodiments of the disclosure;

FIG. 2A shows an ion source tuning system, according to embodiments of the disclosure;

FIG. 2B shows details of an exemplary controller;

FIG. 2C shows one embodiment of a beam line and beam detector geometry;

FIG. 2D shows the geometry of an ion beam and a detector, according to some embodiments;

FIG. 2E shows another ion source tuning system, according to embodiments of the disclosure;

FIG. 3A to FIG. 3E show a plurality of operations for ion source tuning, in accordance with embodiments of the disclosure;

FIGS. 4A-4I depict details of ion source tuning using beam imaging, and Z-axis control, according to various embodiments of the disclosure;

FIGS. 5A-5L depict details of ion source tuning using beam imaging, and Y-axis control, according to various embodiments of the disclosure; and

FIG. 6 depicts an exemplary process flow.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not to be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for ion beam tuning, and more particularly, for ion source tuning, for use in systems such as beamline ion implanters.

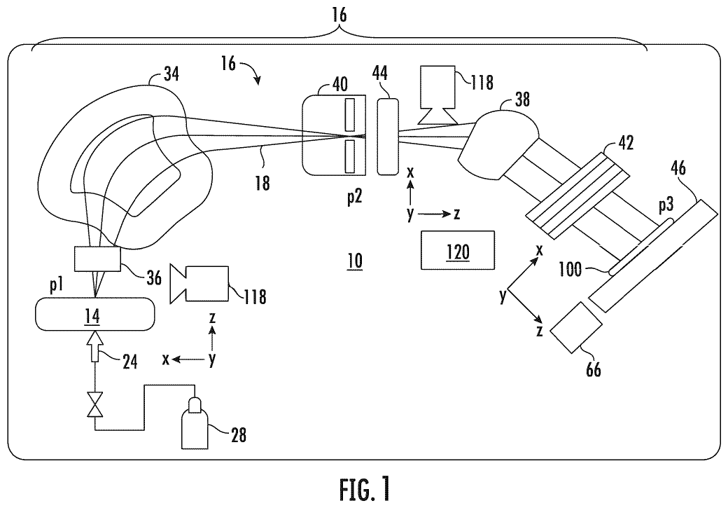

FIG. 1 shows a top view of an exemplary ion implanter, according to embodiments of the disclosure. The ion implantation system 10 may contain, among other components, an ion source 14 for producing an ion beam 18, an ion implanter, and a series of beam-line components 16. The ion source 14 may comprise a ion chamber for receiving a flow of gas 24 and generating ions therein. The ion source 14 may also comprise a power source, and an extraction electrode assembly disposed near the ion chamber. In the view of FIG. 1, the ion source 14 may represent any or all of the above components, including power source, ion chamber, and extraction assembly.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma source known to those skilled in the art.

The ion source 14 may generate the ion beam 18 for processing a substrate 100. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate).

In various embodiments, different species may be used as the ions to be used to deliver an energy-imparting dose of ions into the film. Non-limiting examples of suitable ions include silicon (Si), boron (B), carbon (C), oxygen (O), germanium (Ge), phosphorus (P), arsenic (As), inert gas ions, and so forth, such as other suitable ions, so as to alter substrate stress, substrate OPD, or other properties.

The beam-line components 16 may include, for example, a mass analyzer 34 (such as an analyzing magnet), a first acceleration or deceleration stage 36, a collimator 38, a mass resolving slit 40, and other suitable downstream beamline components such as a quadrupole set (not shown) and an energy filter 42. These components are provided to accelerate the ion beam 18, decelerate the ion beam 18, shape the ion beam 18, scan the ion beam 18, and so forth. In some embodiments, beam monitors, such as current monitors (not separately shown) may be provided at one or more locations along the beamline shown as location p1, location p2, and location p3.

In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate 100 mounted on a platen 46 or clamp within a process chamber. As appreciated, the substrate may be moved using a control mechanism 66 in one or more dimensions (e.g., translate, including scanning, rotate, and tilt). As shown, there may be one or more feed sources 28 operable with the chamber of the ion source 14. As an example, the ion implantation system 10 may include a scanner 44, to scan the ion beam 18. For example, the ion beam 18 may be provided as a spot beam that is scanned with the X-Y plane of the Cartesian coordinate system. For example, a scan generator (not separately shown) may deliver a scan signal, such as an oscillating voltage, to a pair of electrode plates that generate an oscillating electric field at a scan frequency in the kHz range, such as 1 kHz, 2 kHz, 5 kHz, according to some non-limiting embodiments. In other embodiments, the scanner 44 may be omitted, and the ion beam 18 may be provided as an elongated ribbon beam having a long axis that extends along the X-axis, for example. In such embodiments, the substrate 100 may be scanned along the Y-axis, rotated within the X-Y plane, tilted with respect to the Z-axis, and so forth.

The ion implantation system 10 may further include at least one beam-imaging detector, shown as detectors 118, which detectors are arranged to image the ion beam 18, as described below.

As further shown in FIG. 1, the ion implantation system 10 may include a control system or set of control components, shown as controller 120, to control operation of various components of the ion implantation system 10, including components to scan the platen 46, to tilt the platen 46, to scan the ion beam 18, or to adjust the energy of the ion beam 18, for example. The controller 120 may further control operation of various components of the ion implantation system 10 to implement the methods as disclosed herein below.

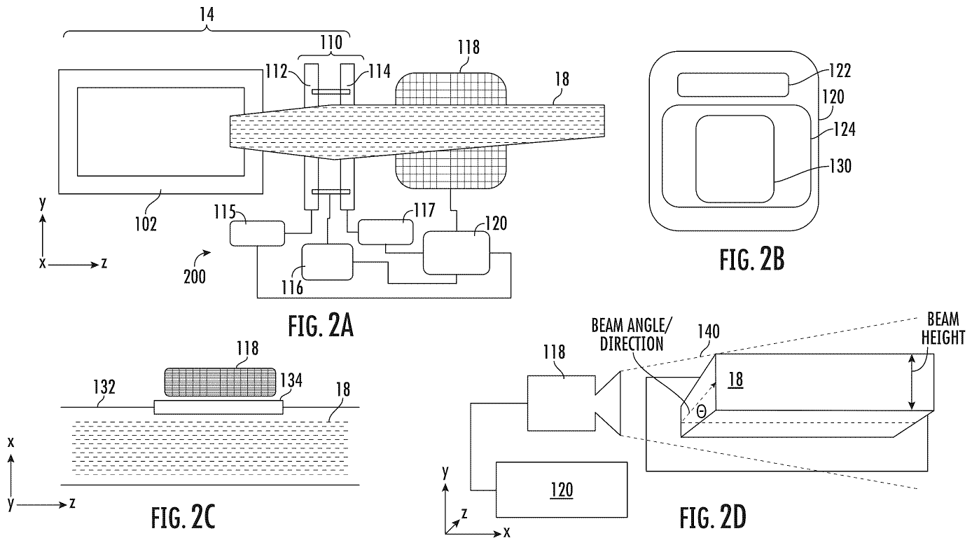

At certain instances, the ion implantation system 10 may be tuned, such as when a new implantation recipe is to be used, such as at regular intervals during an implantation run, or other suitable instance. One aspect of tuning involves tuning of the ion source 14. To that end FIG. 2A shows an ion source tuning system 200, according to embodiments of the disclosure. The ion source tuning system includes ion source 14, electrode control component 116, detector 118, and controller 120. FIG. 2B shows details of an exemplary variant of the controller 120, discussed below. In the embodiment of FIG. 2A, the ion source 14 includes an ion source chamber 102 that generates ions that are extracted to form the ion beam 18. The ion source 14 may further include an electrode set 110, external to the ion source chamber 102, where the electrode set 110 is an adjustable electrode set that is movable with respect to the ion source chamber 102. In one example, the electrode set 110 includes a suppression electrode 112 and a local ground electrode 114. The electrodes of electrode set 110 may be coupled separately to a voltage supply 115 and voltage supply 117 as shown. These two electrodes may be mechanically coupled to one another to move in concert with one another. The potentials of the suppression electrode 112 and local ground electrode 114 may be set to accelerate and extract the ion beam 18.

As further shown in FIG. 2A, a detector 118 is disposed downstream to the electrode set 110. The location of the detector 118 may be at any suitable position along the beamline of the ion implantation system 10. In one embodiment, the detector 118 may be located upstream to the mass analyzer 34. In particular, the detector 118 may be a two-dimensional imaging detector arranged to generate a two-dimensional image of the ion beam 18. In one variant of the arrangement of FIG. 2A, the detector 118 may be arranged in a manner to record an image of the ion beam 18 essentially along an imaging plane that extends parallel to the Y-Z plane, as defined in the figures. The imaging geometry of a detector of the present embodiments is further detailed with respect to embodiments to follow.

In various embodiments, the detector 118 may include an image sensor that is a charge coupled device (CCD) or CMOS based camera without color filters applied over the pixels. This arrangement means that the light intensity pixels of such a detector will generate a response that is in proportion to the overall light intensity in certain regions of the field of view, which light intensity in turn corresponds to ion density in said regions. As such, the variable response of different pixels in the detector 118 as a function of position in the plane of the image sensor of the detector will define an overall ion beam shape.

FIG. 2C shows one embodiment of a beam line and beam detector geometry. In this embodiment, the detector 118 may be mounted on the side of a vacuum chamber 132 or other component that houses and contains the ion beam 18. An optical window 134 may be provided to transmit light that is omitted from the ion beam 18 to detector 118.

To explain in more detail how the detector 118 may image an ion beam 18, note that atoms and molecules ionized by plasma interactions will emit photons upon decay from an excited state either to the ground state, or an intermediate energy state (between excited and ground). Atoms and molecules that occupy the space where the ion beam is present and are energized by interactions with ions in an ion beam will emit light around one or several characteristic energies and wavelengths (and/or bands of both), depending on the specific transitions possible for each component, and the energetics of the ion/molecules/electrons in the system. The intensity (I_{λ}) of a wavelength (λ) or band is directly proportional to the density of the species (n_{A}) and the energy transitions occurring for said species (α_{λA}): I_{λ}=n_{A}*α_{λA}

CMOS and CCD image sensor cells are based on a MOS (metal-oxide-semiconductor), or upon a semiconductor capacitor cell structure that stores charge, and can be read out via additional circuitry (integrated CMOS transistors, by shift registers in the case of CCD, or external circuitry). When light that is generated by species excited by interaction with the ions of an ion beam impacts the sensor cells, charge is generated in the capacitor cells via the photoelectric effect. The amount of charge generated in each cell (q), or “pixel”, is proportional to the free carrier generation rate (G), which rate is dependent on the flux of photons incident on the cell surface (φₛ) and the absorption coefficient of the cell material for the incoming photons (β). Light absorption of a material varies for different photon wavelengths and energies, and therefore so does free carrier generation from the photoelectric effect. Assuming a uniform absorption throughout the cell, the charge in each cell can be related to the cumulative free carrier generation due to all the photons of various wavelengths (λ) can be described by the following relationship:

$$q ∝ G {{\int }^{{λ}_{2}}}_{{λ}_{1}} \{ {β}_{λ} * {ϕ}_{s λ} * exp ( - {β}_{λ} * z ) \} d λ ,$$

where the boundaries of the integral are the boundaries of the light spectrum observable by the pixel cell, and z is the cell depth relative to the surface. The resulting charge held in each pixel can then be read out to a computer for post processing, creating an image where the brightness of each pixel is proportionate to the respective light absorbed. Therefore, the brightness pattern of an array of pixels in a CMOS of CCD detector will serve as an image of the ion beam generating the light. Thus, one may understand that the ions of the ion beam 18 may generate light indirectly by interacting with species that directly emit light, such as atoms and molecules. Referring again to FIG. 2B, in various embodiments, the aforementioned component,

controller 120, may automate the operation of the embodiments as described above with respect to FIGS. 2C-5 below. In this embodiment, the controller 120 may include a processor 122, such as a known type of microprocessor, dedicated processor chip, general purpose processor chip, or similar device. The controller 120 may further include a memory or memory unit 124, coupled to the processor 122, where the memory unit 124 contains a beam control routine 130. The beam control routine 130 may be operative on the processor 122 to manage tuning of an ion beam 18, in order to monitor the ion beam 18, analyze the ion beam 18, ensure that the ion beam 18 satisfies certain criteria, and adjust components, such as components of the ion source 14, including the electrode set 110. In one embodiment, the memory unit 124 of controller 120 may be adapted to store various information, including image information, beam characteristic analysis, and other features, and discussed below.

The memory unit 124 may comprise an article of manufacture. In one embodiment, the memory unit 124 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

Returning to FIG. 2A, the ion source tuning system 200 further includes an electrode control component 116, which component may include at least one of: mechanical members, motors, user interface, electronic processor, and/or software routine, where the electrode control component is coupled to the electrode set 110 to move the electrode set with respect to the ion source chamber 102. For example, upon input from controller 120, the position of electrode set 110 may be adjusted with respect to ion source chamber 102.

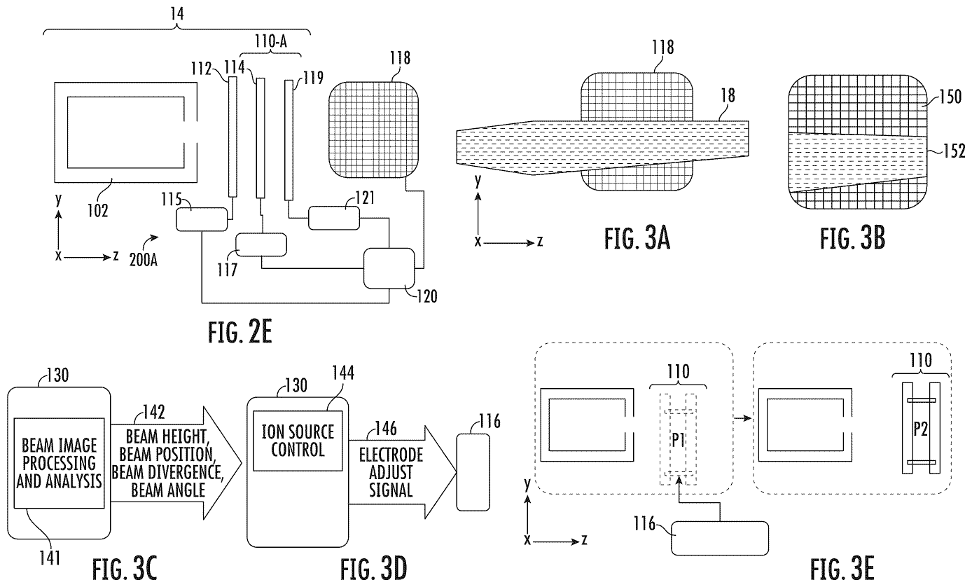

FIG. 2D shows a quasi-end view of the geometry of ion beam 18 and detector 118. The detector 118 may be arranged to receive light over a field of vision 140, as shown by the dotted line. Note that particular species associated with the ion beam 18 will emit radiation that is received by the detector 118, and may be used to form an image of the ion beam 18, as discussed further with respect to FIG. 3B. In particular, the image of the ion beam 18 may represent side view of the ion beam 18 that is generally formed within the Y-Z plane, where the Z-axis of the Cartesian coordinate system used herein may represent the nominal direction of propagation of the ion beam 18 at the position of the location of the detector 118 along the beamline of the ion implantation system 10.

The image of the ion beam 18 recorded at detector 118 may define a particular angle, a particular divergence, a particular position with the image plane of the detector 118, as well as a particular beam height, among other features.

FIG. 2E shows another ion source tuning system 200A, according to embodiments of the disclosure. The ion source tuning system 200A may be similar to the ion source tuning system 200, with like parts labeled the same. A difference is that an electrode set 110A is provided, defining a tetrode system, including the ion source chamber 102. The electrode set 110A includes three electrodes external to the ion source chamber 102, including an electrode 119. Each of the electrodes, suppression electrode 112, local ground electrode 114, and electrode 119 is coupled to a separate voltage supply, shown as voltage supply 115, voltage supply 117, and voltage supply 121. The controller 120 may be coupled to individually adjust the voltage that is supplied to one or more of the electrodes of electrode set 110A.

To further explain operation of the present embodiments, FIG. 3A-3E show a series of operations for tuning an ion beam. In FIG. 3A, an ion beam 18 is extracted and propagates along a beamline, so that the ion beam 118 passes by the detector 118. At FIG. 3B, an image 150 of the environment of the ion beam 18 is recorded by the detector 118. The image 150 may be recorded in a two-dimensional array of pixels, where the ion beam portion 152 of the image 150 generates more light that is registered by the array of pixels as a beam image, with particular shape, size, height, angle, divergence, and so forth. At FIG. 3C, the recorded image is transmitted for processing by the controller 120, such as by the beam control routine 130. The beam control routine 130 may include an image processing and analysis component 141 that generates an output 142. The output 142 may include a set of beam characteristics, such as at least one of: a beam height, a beam position, a beam divergence, a beam angle, among other features. At FIG. 3D an ion source control component 144 may determine, based upon output 142, that the characteristics of the ion beam 18 are to be adjusted. Accordingly, the ion source control component 144 may generate and send to electrode control component 116 a control signal 146 for adjusting the electrode set 110. At FIG. 3E, responsive to the control signal 146 the electrode control component 116 adjusts the position of the electrode set 110, such as from P1 to P2. Note that is some embodiments, the position of the electrode set 110 may be adjusted along the at least one of the Z-axis and the Y-axis.

In some embodiments, the sequence of operations as suggested in FIGS. 3A-3E may be performed in an iterative manner to perform beam tuning, by converging on a position for the electrode set 110 to generate a targeted set of beam characteristics.

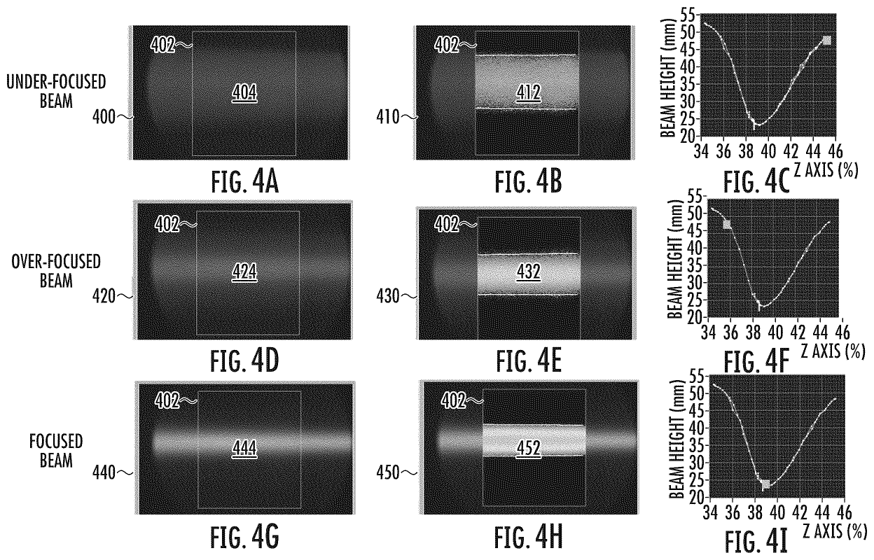

FIGS. 4A-4I depict details of ion source tuning using beam imaging, and Z-axis control, according to various embodiments of the disclosure. As noted above, components of the ion source tuning system 200 may be used to adjust an electrode set 110 to tune an ion beam. In the scenario of FIGS. 4A-4I, an ion source is tuned by moving an electrode set along the Z-axis with respect to an ion source chamber. FIGS. 4A-4C correspond to a first position of the electrode set with respect to ion source chamber along the Z-axis, FIGS. 4D-4F correspond to a second position of the electrode set with respect to ion source chamber along the Z-axis, and FIGS. 4G-4I correspond to a third position of the electrode set with respect to ion source chamber along the Z-axis.

Turning to FIG. 4A there is shown a detected image 400, registered by a detector, such as detector 118. The detected image 400 represents an image of a beamline region that is conducting an ion beam 404 therethrough. In one embodiment, a portion of the detected image 400 is defined as a region of interest, shown as ROI 402. The ROI 402 may serve as a basis to analyze the ion beam 404. In the state of FIG. 4A, the ion beam 404 may be deemed to be in an under-focused condition. Turning to FIG. 4B, there is shown a scenario where an image 410 has been generated, based upon the image 400. The image 410 represents an image where the image portion in the ROI 402 has been filtered to show high contrast and high brightness, where a filtered beam image 412 is generated that represents a filtered image of ion beam 404.

Similarly to FIG. 4A, FIG. 4D presents a detected image 420 for an ion beam 424, this time under an over-focused condition. FIG. 4E shows an image 430 that is derived from the image 420 by filtering the ROI 402 of image 420, similarly to FIG. 4B, to generate a filtered beam image 432 of ion beam 424. Moreover, FIG. 4G presents a detected image 440 for an ion beam 444, this time under a focused condition. FIG. 4H shows an image 450 that is derived from the image 440 by filtering the ROI 402 of image 440 to generate a filtered beam image 452 of ion beam 444.

The filtered beam images of respective FIG. 4B, FIG. 4E, and FIG. 4H may be used to analyze the respective one of ion beam 404, ion beam 424, and ion beam 444, and to adjust the position of an electrode set accordingly along the Z-axis. Turning to FIG. 4C there is shown a graph that depicts the measured beam height of ion beam 404, which measurement may be based upon filtered beam image 412, shown as a function of Z-axis position. In this case, the electrode set is disposed at a Z-axis position 46%, which position yields a measured beam height of 47.5 mm. Turning to FIG. 4F there is shown a graph that depicts the measured beam height of ion beam 424, which measurement may be based upon filtered beam image 432, shown as a function of Z-axis position. In this case, the electrode set is disposed at a Z-axis position 36%, which position yields a measured beam height also of 47.5 mm. Turning to FIG. 4I there is shown a graph that depicts the measured beam height of ion beam 444, which measurement may be based upon filtered beam image 452, shown as a function of Z-axis position. In this case, the electrode set is disposed at a Z-axis position 39%, which position yields a measured beam height of just 24 mm. From these measurements, a determination may be made that the Z-axis position 39% for the electrode set represents a focused condition. Note that the curve shown in each of FIG. 4C, FIG. 4F, and FIG. 4I may represent the results of many measurements where beam height is recorded as a function of Z-axis position of the electrode set. Accordingly, the focused condition for Z-axis position of the electrode set may be determined to a high degree of accuracy.

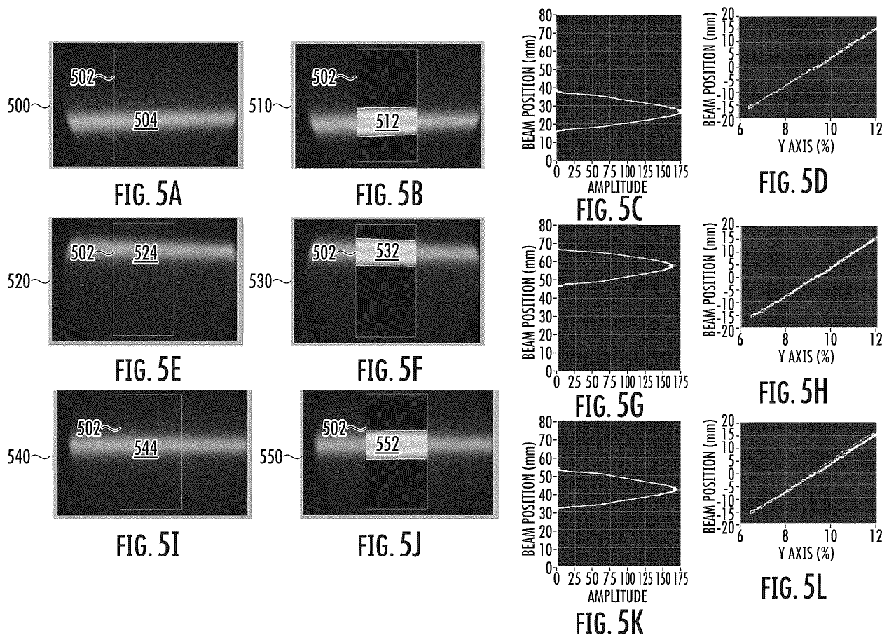

FIGS. 5A-5L depict details of ion source tuning using beam imaging, and Y-axis control, according to various embodiments of the disclosure. In the scenario of FIGS. 5A-5L, an ion source is tuned by moving an electrode set along the Y-axis with respect to an ion source chamber. FIGS. 5A-4D correspond to a first position of the electrode set with respect to ion source chamber along the Y-axis, FIGS. 5E-4H correspond to a second position of the electrode set with respect to ion source chamber along the Z-axis, and FIGS. 4I-5L correspond to a third position of the electrode set with respect to ion source chamber along the Y-axis.

Turning to FIG. 5A there is shown a detected image 500, registered by a detector, such as detector 118. The detected image 500 represents an image of a beamline region that is conducting an ion beam 504 therethrough. In one embodiment, a portion of the detected image 500 is defined as a region of interest, shown as ROI 502. The ROI 502 may serve as a basis to analyze the ion beam 504. In the state of FIG. 5A, the ion beam 504 may be deemed to be in low position. Turning to FIG. 5B, there is shown a scenario where an image 510 has been generated, based upon the image 500. The image 510 represents an image where the image portion in the ROI 502 has been filtered to show high contrast and high brightness, where a filtered beam image 512 is generated that represents a filtered image of ion beam 504.

Similarly to FIG. 5A, FIG. 5E presents a detected image 520 for an ion beam 524, this time in a low beam position. FIG. 5F shows an image 530 that is derived from the image 520 by filtering the ROI 402 of image 520, similarly to FIG. 5B, to generate a filtered beam image 532 of ion beam 524. Moreover, FIG. 5I presents a detected image 540 for an ion beam 544, this time when the ion beam 544 is in a center position. FIG. 5J shows an image 550 that is derived from the image 540 by filtering the ROI 402 of image 540 to generate a filtered beam image 552 of ion beam 544.

The filtered beam images of respective FIG. 5B, FIG. 5F, and FIG. 5J may be used to analyze the respective ion beam 504, ion beam 524, and ion beam 544, and to adjust the position of an electrode set accordingly along the Y-axis. Turning to FIG. 5C, FIG. 5G, and FIG. 5K there are shown a set of respective graphs that depicts the detected amplitude of the beam at a given pixel of the detector as a function of position along the Y-axis, which measurement may be based upon filtered beam images (512, 532, 552, respectively), and is proportional to the local beam current density. These graphs may be used to locate the exact position of the ion beam 504, ion beam 524, ion beam 544, so that the location for placing the electrode set at a suitable position along the Y-axis is better determined. FIG. 5D, FIG. 5H, and FIG. 5L are graphs that plot the position of a measured ion beam at the detector as a function of the relative location along the Y-axis of the electrode set with respect to an ion source chamber. The data points in FIG. 5D, FIG. 5H, and FIG. 5L are derived from the pixel maxima of the graphs of FIG. 5C, FIG. 5G, and FIG. 5K, respectively.

Note that in the embodiments related to FIG. 4A to FIG. 5L the electrode set includes a suppression electrode and an acceleration electrode that are moved in concert with one another, so that when the electrode set is moved with respect to an ion source chamber, the suppression electrode and the acceleration electrode move in the same relative manner and to the same extent with respect to the ion source chamber. However, in additional embodiments, and electrode set may be configured differently. For example, a tetrode or pentode electrode system may be used in additional embodiments, where at least one electrode is independently movable with respect to at least one other electrode of the electrode set. Thus, when the electrode set is moved with respect to an ion source chamber in these additional embodiments, this movement may entail moving all of electrodes that are external to the ion source chamber in concert with one another, or may entail moving at least one electrode in a first manner, while moving at least one other electrode in a second manner, different from the first manner. In some embodiments, a first electrode of the electrode set may remain stationary with respect to the ion source chamber, while at least one other electrode may be moved with respect to the ion source chamber.

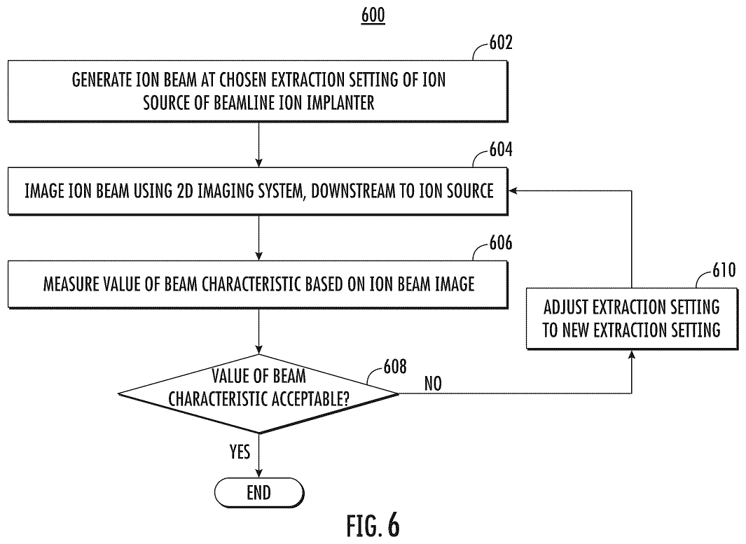

FIG. 6 depicts an exemplary process flow 600.

At block 602, an ion beam is generated at a chosen extraction setting of ion source of beamline ion implanter. The chosen extraction setting may correspond to a first position of an electrode set of the ion source with respect to the ion source chamber of the ion source.

At block 604, the ion beam is imaged using a detector, such as a 2D imaging system, located downstream to ion source. In different non-limiting embodiments, the detector may be CCD device or CMOS detector that generates a measured beam image.

At block 606, a value of a beam characteristic is determined based upon the measured beam image provided by the detector. At decision block 608 a determination is made as to whether the value of the determined beam characteristic is acceptable. For example, a target beam height may be known beforehand as representing a tuned ion beam. Accordingly, if a determined beam characteristic is the beam height, and the determined beam height at block 606 corresponds closely the target beam height, the value of the determined beam characteristic would be acceptable. If so, the process ends. If not, the flow proceeds to block 610.

At block 610, the ion source is adjusted to a new extraction setting, such as changing a position of the electrode set with respect to ion source chamber along a Z-axis or Y-axis, as defined herein. In some embodiments, the adjusting to a new extraction setting may involve moving one electrode of an electrode set with respect to another electrode of the electrode set. In other embodiments, adjusting to a new extraction setting may involve moving a pair of electrodes of the electrode set with respect to an ion source chamber. In further embodiments, adjusting to a new extraction setting may involve adjusting the voltage that is applied to one or more electrodes of an electrode set. For example, in a tetrode or pentode system having three external electrodes or four external electrodes, respectively, that are external to an ion source chamber, the voltages that are applied to one or more of the external electrodes may be independently varied from a previous voltage setting. The flow then returns to block 604.

In summary, advantages provided by the approach of the present embodiments include at least the following. As one advantage, the amount of tuning effort to tune an ion source may be substantially reduced using the beam imaging approach that provides a direct image of the ion beam at a given location, such as near the ion source. Moreover, the beam imaging approach also facilitates more accurate positioning of an electrode set for optimum beam tuning.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implanter, comprising:
an ion source, to generate an ion beam
wherein the ion source comprises:
an ion source chamber; and
an adjustable electrode set, external to the ion source chamber;
a set of beamline components, disposed along a beamline of the ion implanter, and arranged to direct the ion beam to a substrate position; and
an in-situ beam imaging system, having at least one detector that images the ion beam in at least one location, between the ion source and the substrate position.

2. The ion implanter of claim 1, wherein the at least one detector comprises a two-dimensional array of pixels, arranged to intercept light generated by the ion beam.

3. The ion implanter of claim 2, wherein the two-dimensional array of pixels is arranged in an imaging plane that extends parallel to a local direction of propagation of the ion beam.

4. The ion implanter of claim 1, wherein the detector is disposed between the ion source and an analyzing magnet.

5. The ion implanter of claim 1, wherein the detector is disposed downstream of an analyzing magnet.

6. The ion implanter of claim 1, further comprising a control system, the control system comprising:
a processor; and
a memory unit coupled to the processor, including a beam control routine, the beam control routine operative on the processor to:
receive an image of the ion beam from the at least one detector;
filter the image to generate a filtered beam image; and
determine at least one beam characteristic from the filtered beam image.

7. The ion implanter of claim 6, wherein the at least one beam characteristic is a beam height, a beam position, a beam divergence, and a beam angle.

8. The ion implanter of claim 7, wherein the control system is arranged to send a control signal to adjust a position of the adjustable electrode set with respect to the ion source chamber, based upon to the at least one beam characteristic.

9. The ion implanter of claim 7, wherein the control system is arranged to send a control signal to adjust a voltage that is applied to at least one electrode of the adjustable electrode set, based upon the at least one beam characteristic.

10. A method of controlling an ion beam in an ion implanter, comprising:
measuring a beam characteristic of the ion beam at a position along a beamline of the ion implanter between an ion source and a substrate position, using a metrology system that includes an imaging detector; and
adjusting an electrode set of the ion source, according to the beam characteristic.

11. The method of claim 10, wherein the imaging detector comprises a two-dimensional array of pixels, arranged to intercept light generated by the beam.

12. The method of claim 11, wherein the two-dimensional array of pixels is arranged in an imaging plane that extends parallel to a local direction of propagation of the ion beam.

13. The method of claim 12, wherein the imaging plane is disposed between the ion source and an analyzing magnet.

14. The method of claim 10, wherein the imaging detector is disposed downstream to an analyzing magnet.

15. The method of claim 10, wherein the ion source further comprises an ion source chamber, wherein the electrode set comprises a suppression electrode and an accelerating electrode that are mechanically coupled to one another, wherein the adjusting the electrode set comprises moving the suppression electrode and the accelerating electrode in concert with one another, with respect to the ion source chamber.

16. The method of claim 15, wherein the adjusting the electrode set comprises at least one of:
moving the electrode set along a direction of propagation of the ion beam; and
moving the electrode set along a perpendicular direction to the direction of propagation of the ion beam.

17. The method of claim 15, wherein a position of the electrode set is automatically moved with respect to the ion source chamber, according to the beam characteristic, using a control system of the ion implanter.

18. The method of claim 10, wherein the ion source further comprises an ion source chamber, wherein the electrode set comprises three electrodes or four electrodes that are external to the ion source chamber, wherein the adjusting the electrode set comprises adjusting a voltage that is applied to at least one electrode of the electrode set, based upon the beam characteristic, using a control system of the ion implanter.
